(19) United States
(12) Patent Application Publication
(10) Pub. No.: US 2005/0056949 A1
(43) Pub. Date: Mar. 17, 2005

(54) Discrete semiconductor component

(75) Inventors: Michael Doscher, Aachen (DE); Axel Schlicht, Ramshausen (DE); Johannes Rabobsky, Hamburg (DE)

Correspondence Address: PHILIPS INTELLECTUAL PROPERTY & STANDARDS, P.O. BOX 3001, BRIARCLIFF MANOR, NY, 10510, US

(73) Assignee: Koninklijke Philip Electrics N.V.

(21) Appl. No.: 10/500,765

(22) PCT Filed: Dec. 18, 2002
(86) PCT No.: PCT/IB02/05491

(30) Foreign Application Priority Data
Jan. 12, 2002 (DE) 10200932.5

(51) Int. Cl. H01L 23/48

(52) U.S. Cl. 257/784

(57) ABSTRACT

A discrete semiconductor component, and in particular a magnetoresistive sensor, having an active circuit that is provided in an active layer (10) on the surface of a substrate, at least one bond pad (12,14,16,18) that forms a bonding surface for a bond wire (22,24,26,28), and electrical connections (20) between the at least one bond pad and the active circuit, is characterized in that the bond pad or pads (12,14,16,18) is or are arranged above the active layer (10).

The invention relates to a discrete semiconductor component, and in particular to a magnetoresistive sensor, having an active circuit that is provided in an active layer on the surface of a substrate, having at least one bond pad that forms a bonding surface for a bond wire, and having electrical connections between the at least one bond pad and the active circuit.

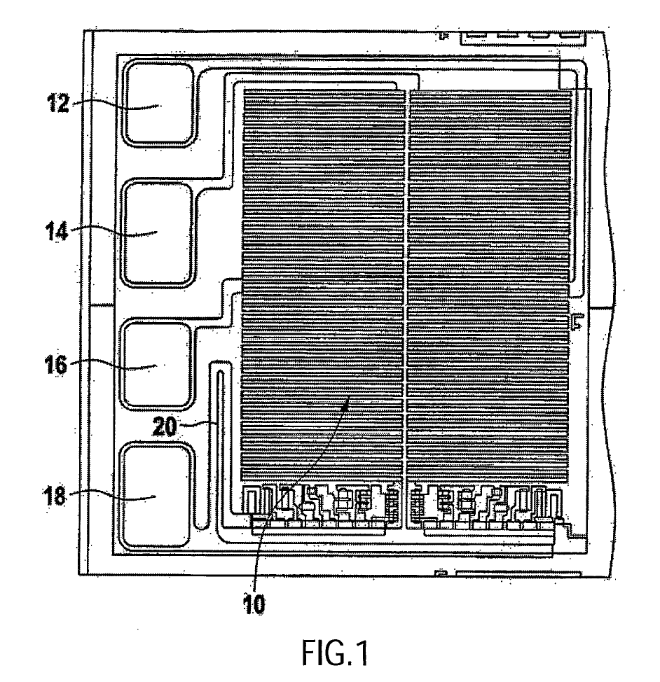

A discrete component of this kind in the form of a magnetoresistive sensor is shown in the layout drawing in FIG. 1. Magnetoresistive sensors are used to measure values such as the angle, phase relation, linear position and speed of rotation of driving or driven gearwheels, use being made for this purpose of the anisotropic magnetoresistive effect. From an active layer marked 10, electrical connections such as 20 lead to bond pads 12, 14, 16, 18 that are generally composed of aluminum or an aluminum alloy and to which a metal bond wire, preferably of gold or a gold alloy, is applied, normally in a ball or wedge bond, to enable electrical contact to be made between the chip and its surroundings. These bond pads and the active layer are arranged next to one another on a chip. Bond pads may not be of less than a minimum size of, typically, 60 μm×60 μm to 100 μm×100 μm and they thus occupy a significant proportion of the total area of the chip. The positions defined for them in the chip layout also determine the forms of package in which the chips can be inserted, which greatly restricts flexibility as far as use in packages of different types is concerned.

It is an object of the present invention to so arrange the discrete semiconductor component described above that the chip area is considerably reduced, combined with an increase in flexibility in respect of the forms of package to be used.

This object is achieved by a discrete semiconductor component as claimed in claim 1. Advantageous embodiments form the subjects of the dependent claims. A method of producing a discrete semiconductor component of this kind is described in claim 7.

Provision is made in accordance with the invention for the bond pad or bond pads to be arranged above the active layer. This “bond pad on active circuit” arrangement is known for integrated circuits and is described in, for example, WO00/35013. However, it has never yet been used in discrete semiconductor components because there has been a fear that the bonding would damage the sensitive layers situated beneath. It has been found that this can be avoided. In accordance with the invention, it is now possible in this way to achieve a considerable reduction in the area needed for the chip, which area is now defined substantially by the area of the active layer.

In a preferred embodiment, the bond pad or bond pads may cover the active layer substantially completely. This has the advantage that a bond connection can be made in virtually any direction in space, thus making it possible for the most varied forms of package to be used without changing the layout of the chip. With this embodiment of the invention, it is also possible for the EMC sensitivity of magnetoresistive sensors to be appreciably reduced without the need for an additional layer of metallization to be introduced. The bond pads have a screening effect against incoming high-frequency alternating fields and, with the passivating layer that may, if required, be situated beneath them, a capacitive effect, through which passivating layer the electrical connections from the bond pads to the active layer are also made.

The passivating layer is preferably of silicon oxide or silicon nitride and produces a capacitive effect with the bond pads. The bond pads may be composed of aluminum or an aluminum alloy in this case.

The bond wires that are applied to the bond pads are preferably composed of gold or a gold alloy.

A method of producing a discrete semiconductor component has the following steps:
providing a substrate having an active layer that has an active circuit,
applying a passivating layer to the active layer, and is characterized by
the arrangement of one or more bond pads on the passivating layer and
the through-passage of electrical connections from the bond pad or pads to the active circuit.

The invention advantageously combines a significant reduction in the area of the chip, an independence of given forms of package and, where necessary, the use of the bond pads, which then have to be made sufficiently large, as a means of electromagnetic screening. However, in connection with the latter point care must be taken that the connection in parallel of the magnetoresistive resistance structures via the capacitors that are formed does not produce, for the system as a whole, time constants that give rise to undesirably slow behavior by the system or to unwanted oscillations.

These and other aspects of the invention are apparent from and will be elucidated with reference to the embodiments described hereinafter.

In the drawings:

FIG. 1 shows a layout of a prior art magnetoresistive sensor;

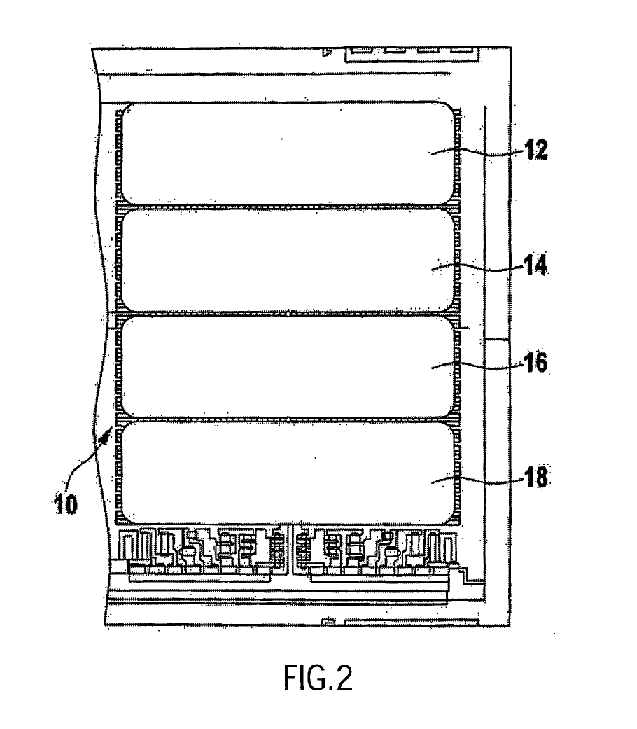

FIG. 2 shows the layout of a magnetoresistive sensor forming one embodiment of the present invention; and

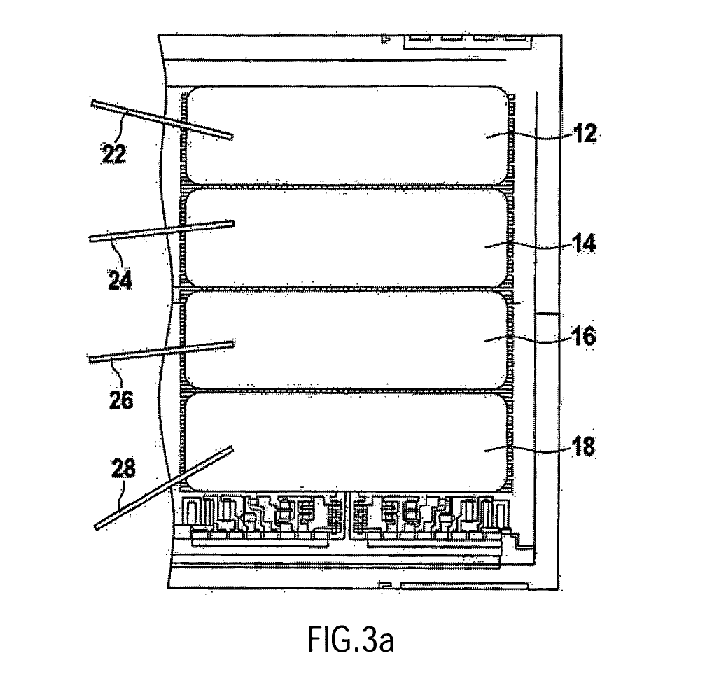

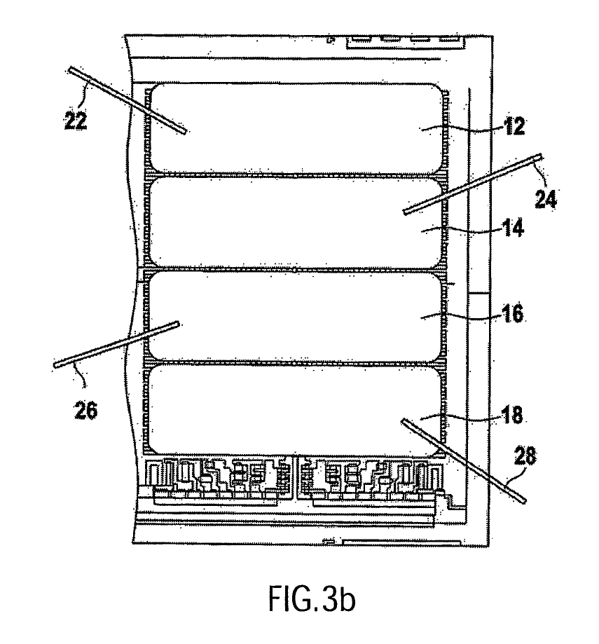

FIG. 3 shows, in parts (a) and (b), different possible arrangements for bond wires.

FIG. 2 shows the arrangement according to the invention of bond pads 12, 14, 16, 18 on the active layer 10 of a magnetoresistive sensor. The bond pads 12, 14, 16, 18 are so designed that they substantially cover the active layer 10. This causes the bond pads 12, 14, 16, 18 to have a screening effect. The layout also provides variable possibilities for connecting bond wires.

Two examples are shown in FIG. 3(a) and FIG. 3(b). FIG. 3(a) shows bonds wires 22, 24, 26, 28 that are all connected to the bond pads 12, 14, 16, 18 on the same side of the active areas. Without changing the layout, it is possible for the connections to be made to two sides of the layout alternately so that, for example, as shown in FIG. 3, bond wires 22, 26 and bond wires 24, 28, which are fixed to bond pads 12, 16 and 14, 18 respectively, are connected to opposite sides of the active area.

The discrete semiconductor component according to the invention may be used wherever the corresponding discrete semiconductor components that do not employ a “bond pad on active circuit” arrangement are used.

1. A discrete semiconductor component, and in particular a magnetoresistive sensor, having
an active circuit that is provided in an active layer (10) on the surface of a substrate,
at least one bond pad (12, 14, 16, 18) that in each case forms a bonding surface for a bond wire (22, 24, 26, 28), and
electrical connections (20) between the at least one bond pad and the active circuit,
characterized in that the bond pad or pads (12, 14, 16, 18) is or are arranged above the active layer (10).

2. A discrete semiconductor component as claimed in claim 1, characterized in that the bond pad or pads (12, 14, 16, 18) cover the active layer (10) substantially completely.

3. A discrete semiconductor component as claimed in claim 1, characterized in that the electrical connections pass through a passivating layer to the active layer (10).

4. A discrete semiconductor component as claimed in claim 3, characterized in that the passivating layer contains silicon oxide or silicon nitride.

5. A discrete semiconductor component as claimed in claim 1 characterized in that the bond pads (12, 14, 16, 18) are composed of aluminum or an aluminum alloy.

6. A discrete semiconductor component as claimed in claim 1, characterized in that the bond wire (22, 24, 26, 28) is composed of gold or a gold alloy.

7. A method of producing a discrete semiconductor component, having the steps of
providing a substrate having an active layer that has an active circuit,
applying a passivating layer to the active layer, characterized by
the arrangement of one or more bond pads on the passivating layer and
the through-passage of electrical connections from the bond pad or pads to the active circuit.
